(19) United States
(12) Patent Application Publication
(10) Pub. No.: US 2009/0278263 A1
(43) Pub. Date: Nov. 12, 2009

(54) RELIABILITY WCSP LAYOUTS

(75) Inventors: Robert Fabian McCarthy, Dallas, TX (US); Stanley Craig Beddingfield, McKinney, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 12/118,078

(22) Filed: May 9, 2008

(51) Int. Cl. H01L 23/52; G06F 9/455

(52) U.S. Cl. 257/778; 716/11; 257/E23.141

(57) ABSTRACT

An integrated circuit device includes a functional circuit die with a patterned rewiring layer defining a first rewiring pad and one or more second rewiring pads on opposite sides of a neutral point of the die. The device also includes at least one dielectric layer having bump opening features over the rewiring pads. The device further includes electrically conductive bump pad features formed on the dielectric layer over the bump opening features. The bump pad features make contact with the rewiring pads via the bump opening features. In the device, a center of the bump opening features are laterally offset from a center of the bump pad feature towards a neutral point of the die.

### FIELD OF THE INVENTION

The present invention is directed to the field of wafer-level chip scale packages (WCSPs) for integrated circuits, and more particularly to designs and related methods for improving reliability of WCSPs.

### BACKGROUND

The demand for smaller, more portable electronic products with increased functionality has been fueling growth in many markets and applications. To provide these products, designers have been turning to reduced size packing methods such chip scale packages (CSPs). According to IPC's standard J-STD-012, “Implementation of Flip Chip and Chip Scale Technology”, to qualify as being “chip scale”, the package must have an area no greater than 1.2 times that of the die that is being packaged and it has to be a single-die, direct surface mountable package. Another criterion that is often applied to qualify these packages as CSPs is that their ball pitch should be no more than 1 mm.

One particular implementation of CSPs, wafer-level CSPs (WCSPs), allows the package size to be reduced to the size of the die itself and eliminates the need for the larger interposer layer typical of larger CSPs. To fabricate WCSPs, once the dies are formed using a conventional semiconductor fabrication process, the electrode pads of the dies can be coupled via a redistribution layer (RDL), formed in patterned interlayer dielectric films deposited on the dies, to an array of solder balls formed on exposed portions of the RDL. The interlayer dielectric films for WCSPs are generally deposited dielectric polymer films, such as bisbenzocyclobutene (BCB) or polyimides. The portions of the RDL and the solder balls contacting the electrode pads and the RDL, respectively, can include one or more adhesion or diffusion barrier layers formed therebetween.

The reliability of WCSPs (and other package types in general) is generally evaluated via the results of board level temperature cycle testing. That is, the WCSPs are mounted onto organic printed circuit boards and subjected to temperature cycling and the properties of the RDL and the solder balls, as well as the properties of any adhesion or diffusion barrier layers used therebetween, are evaluated. With a small number of solder balls formed on the WCSPs, reliability is generally found to be sufficient. However, in the case of WCSPs with large numbers of solder balls, the reliability of the WCSPs may degrade and result in an unacceptably high number of field failures.

### SUMMARY OF THE INVENTION

This Summary is provided to comply with 37 C.F.R. §1.73, requiring a summary of the invention briefly indicating the nature and substance of the invention. It is submitted with the understanding that it will not be used to interpret or limit the scope or meaning of the claims.

With an ever increasing number of input and output terminals included in WCSPs, the number of solder balls and the size of the array of solder balls has also increased. However, die size has decreased and the stress induced by the multiple layers deposited on semiconducting substrates has also increased. The Present Inventors have identified that increased stress has also resulted in increased warping of diced dies, particularly along their edges. For small packages, such as WCSPs, the Present Inventors have discovered that these stresses are generally sufficient to cause peeling and cracking of the interlayer dielectric films deposited on the dies, resulting in degraded reliability of the RDL and the solder ball connections to the electrode pads. In response to these problems, embodiments of the present invention provide a modified layout scheme that substantially overcomes the above described deficiencies for WCSPs. In particular, the Present Inventors have discovered that by shifting the position of vias in the interlayer dielectric films for contacting under-bump metallization (UMB) layers and the underlying RDL towards a neutral stress point of the die, peeling and cracking of the interlayer dielectric films can be mitigated, resulting in improved reliability of the RDL and the solder ball connections to the electrode pads.

In a first embodiment of the present invention, an integrated circuit device is provided. The device can include a functional circuit die and a patterned rewiring layer formed on the die, the patterned rewiring layer defining a first rewiring pad and one or more second rewiring pads on an opposite side of a neutral point of the die. The device can further include at least one dielectric layer formed on the patterned rewiring layer and the functional circuit die, the dielectric layer having a first bump opening feature over the first rewiring pad and a second bump opening feature over each of the second rewiring pads. The device can also include an electrically conductive first bump pad feature formed on the dielectric layer over the first bump opening feature and electrically conductive second bump pad features formed on the dielectric layer over each of the second bump opening features. In the device, the first and the second bump pad features make contact with the first and the second rewiring pads via the first and the second bump opening features. Also in the device, a center of the first bump opening feature is laterally offset from a center of the first bump pad feature towards the neutral point of the die and a center of each of the second bump opening features is laterally offset from a center of the associated second bump pad feature towards the neutral point of the die.

In a second embodiment of the present invention, a mask set for an integrated circuit device is provided. The mask set can include a plurality of masks for forming a functional circuit die. The mask set can also include a rewiring layer mask for forming a patterned a rewiring layer on the die, the patterned rewiring layer defining a first rewiring pad and one or more second rewiring pads on an opposite side of a neutral point of the die. The mask set can also include a bump opening mask layer for forming in at least one dielectric layer formed on the patterned rewiring layer and the functional circuit die a first bump opening feature over the first rewiring pad and a second bump opening features over each of the second rewiring pads. The mask set can further include a bump pad mask for forming in an electrically conductive layer over the dielectric layer a first bump pad feature over the first bump opening feature and a second bump pad features over each of the second bump opening features. In the mask set, the first and the second bump pad features make contact with the first and the second rewiring pads via the first and the second bump opening features. Furthermore, a center of the first bump opening feature is laterally offset from a center of the first bump pad feature towards the neutral point of the die and a center of each of the second bump opening features is laterally offset from a center of the associated second bump pad feature towards the neutral point of the die.

In a third embodiment of the present invention, a method for designing an integrated circuit device is provided. The method can include providing a functional circuit die design and identifying a neutral point of the die. The method can also include generating a rewiring layer design for forming a patterned a rewiring layer on the die, the patterned rewiring layer defining a first rewiring pad and one or more second rewiring pads on an opposite side of the neutral point of the die. The method can further include generating a bump opening layer design for forming in at least one dielectric layer formed on the patterned rewiring layer and the functional circuit die a first bump opening feature over the first rewiring pad and a second bump opening features over each of the second rewiring pads. The method also includes generating a bump pad layer design for forming in an electrically conductive layer over the dielectric layer a first bump pad feature over the first bump opening feature and a second bump pad features over each of the second bump opening features. In the method, the first and the second bump pad features are designed to make contact with the first and the second rewiring pads via the first and the second bump opening features. Furthermore, a center of the first bump opening feature is laterally offset from a center of the first bump pad feature towards the neutral point of the die and a center of each of the second bump opening features is laterally offset from a center of the associated second bump pad feature towards the neutral point of the die.

### BRIEF DESCRIPTION OF THE DRAWINGS

FIG. 1 shows an exemplary stress distribution of pads on a WCSP device.

FIG. 2 shows an exemplary stress distribution pattern in a under bump metallization (UMB) layer on a WCSP device.

FIG. 3 shows a cross-section view of a portion of a WCSP device according to an embodiment of the present invention.

FIG. 4 shows an exemplary layout of a portion of a WCSP device according to an embodiment of the present invention.

FIG. 5 shows another exemplary layout of a portion of a WCSP device according to an embodiment of the present invention.

### DETAILED DESCRIPTION OF THE DRAWINGS

The present invention is described with reference to the attached figures, wherein like reference numerals are used throughout the figures to designate similar or equivalent elements. The figures are not drawn to scale and they are provided merely to illustrate the instant invention. Several aspects of the invention are described below with reference to example applications for illustration. It should be understood that numerous specific details, relationships, and methods are set forth to provide a full understanding of the invention. One having ordinary skill in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

Embodiments of the present invention provide designs and related methods for improving reliability of integrated circuit devices, such as wafer level chip scale package (WCSP) integrated circuit (IC) devices. As previously described, one of the main issues regarding use of WCSP devices is their reliability, typically evaluated using temperature cycling testing. For example, BLR-temperature cycle testing (−40 C. to +125 C.) using JEDEC standard JESD22-A104-B finds WCSP devices to typically have a increase in overall net resistance of 20%, considered a reliability failure. Several techniques have been attempted to improve reliability of WCSP devices, typically involving changes in materials and/or changes in thickness of materials used for forming the redistribution layer (RDL), interlayer dielectric films, the under bump metallization (UMB) layer, and the solder balls in WCSP devices. However, even such “improvements” still generally result in WCSP devices having poor reliability as compared to other packaging technologies.

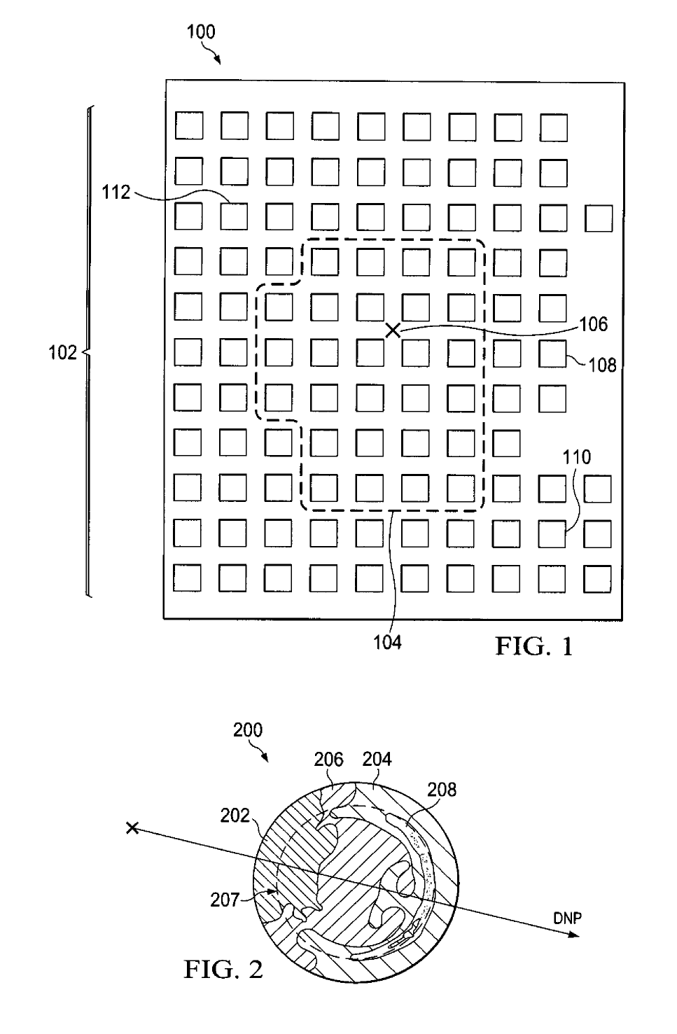

The Present Inventors have discovered that such changes in materials comprise only limited effects on WCSP device reliability. The driver effecting reliability of WCSP devices, particularity for die sizes over 9 mm² with at least a large number of solder balls (>80) is stress induced by the differences in CTE (coefficient of thermal expansion) between the WCSP device and the organic PCB. As temperatures change the PCB wants to expand relative to the WCSP device, resulting in compressive and tensile forces in various layers in diced WCSP dies. In particular, such forces are increased for portions of the diced die closer to the edges, increasing stress in such regions, especially in the vicinity of UMB pads (bump pads) of the WCSPs dies. Accordingly, as the distance of a UMB pad to a neutral stress point (DNP), normally the center of a die, on the diced die is increased, the stress at the UMB pad is also increased. An exemplary stress distribution pattern for UMB pads 102, including pads 108, 110, and 112, on a WCSP die 100 is shown in FIG. 1.

As a result of the various forces described above, the amount of physical stress on each of the UMB pads 102 can vary. The Present Inventors have found that the stress in die 100, is generally radial in nature, due to the increased amount of bowing along the edges of the diced WCSP die 100. Therefore, as the distance between a UMB pad 102 and the neutral point 106 of the WCSP die 100 (DNP) increases, stress on the UMB pads 102 can also increase. However, the stress pattern is not necessarily uniform across the WCSP die 100. For example, the stress pattern can be minimal in a central region 104 of the WCSP die 100. This minimal stress is typically associated with the UMB pads 102 closest to the neutral point 106 (i.e., UMB pads 102 having a lower DNP) of the diced WCSP die 100. A “neutral point of a diced die” as used herein refers to the point in the diced die in which the stress is minimized or is zero. Typically, the neutral point 106 is at or near the geometric center of the die 100.

In some cases, the neutral point 106 can offset from the geometric center of the die 100 based on the number, type, and pattern of layers formed on the die. For example, in the case of a functional circuit formed with high and low density regions of functional circuits, the variations in density (and therefore variations in functional circuit layers) can result in variations in diced die stress which can cause a neutral point to be offset from the geometric center of the diced die. In another example, as the shape of the WCSP die varies, local and global variations in bowing can also offset the neutral point of the WCSP die from its geometric center.

A “distance to a neutral point” or “DNP”, as used herein refers to a distance from the neutral point to the center of a feature. In the case of overlapping and aligned features, the DNP would be the same for all features. For example, in the case of a series of concentric overlapping shapes, such as a group of concentric circular or rectangular features defining layers of vias and conductors, the DNP for each of the features is measured from the neutral point to the geometric center of the features. However in some cases, the shapes may not be concentric. In such cases, the DNP for each of the features is measured from the geometric center of each feature. However, a number of related features can be formed in a layer and be associated with a single feature. For example, two or more vias can be used to connect two pads in different layers. In such cases, the multiple vias can be considered to comprise a single feature and thus the DNP can be measured from the geometric center of the vias.

However, while the overall DNP of the UMB pads 102 is generally the primary factor affecting reliability, is not the only factor. For example, in a typical die, the stress in UMB pad 108 will generally be less that that in UMB pad 110. The Present Inventors have found that for UMB pads formed closer to the corners of the die, such as UMB pad 110, the stress is generally further enhanced, resulting in a greater likelihood of reliability failures. Additionally, the stress can also be further enhanced for UMB pads having the same DNP due to other effects. For example, variations in functional circuit density, as described above, can also result in local variations in the radial stress pattern. In another example, variations in WCSP die size and shape can also result in variations in stress.

An exemplary stress pattern 200 for a UMB pad is illustrated in FIG. 2. As shown in FIG. 2, stress is distributed along the UMB pad primarily as a function of DNP. For example, region 202, having the lowest DNP of the UMB pad, is associated the lowest stress levels. Conversely, region 204, having the largest DNP, is associated with the larger stress levels. An intermediate region 206, is associated with stress levels falling between the that of regions 202 and 204. However, other features can also modify the stress in the UMB layer. In particular, the region of the UMB pad adjacent to a via 207 formed to contact the RDL (i.e., bump vias) can be enhanced. In regions 202 and 206, the enhanced stress is negligible, but this stress can become significant in region 204, already under a high stress, resulting in a region of enhanced stress 208 along the edge of the bump via. In region 208, this additional stress can further enhance existing stress in the interlayer dielectric films and the RDL, causing cracking and peeling in these layers. Such cracking and peeling can lead to reliability failures, especially in layout having RDL contact traces associated with a bump via running proximate to high stress region 208.

Accordingly, embodiments of the present invention provide new layout schemes for mitigating the influence of local and global stress on the UMB pads. In particular, the various embodiments of the present invention provide for lowering a DNP of the bump via by applying a lateral offset for bump vias as compared to bump pads. That is, by shifting the position of one or more bump vias towards the neutral point of the die. This is in contrast to conventional methods for producing shifted bump vias using existing masks. Generally, conventional methods result in offset bump vias that are all offset in a same direction. For example, in the case of misalignment, some vias will be offset towards the neutral point. However, vias on an opposite side of the neutral point will be offset away from the neutral point. Consequently, vias on opposite sides of the neutral point cannot be shifted towards a neutral point at or proximate to the center of the die. In contrast, the various embodiments of the present invention provide for ICs, mask sets, and designs that specifically shift vias on opposite sides of the die, such as vias for pads 110 and 112, in a direction towards a neutral point of the die. As used herein, a first and second via are on opposite sides of a neutral point if at least one component of the directional vector for each of the vias towards the neutral point are in opposing directions.

By applying such lateral offsets to existing WCSP designs, the present inventors have found that normal stress on the RDL layer can be reduced by 30% and shear stress can be reduced by 13%. The reduced stress can lower the likelihood of cracking or peeling in the RDL contact traces, reducing the likelihood of reliability failures.

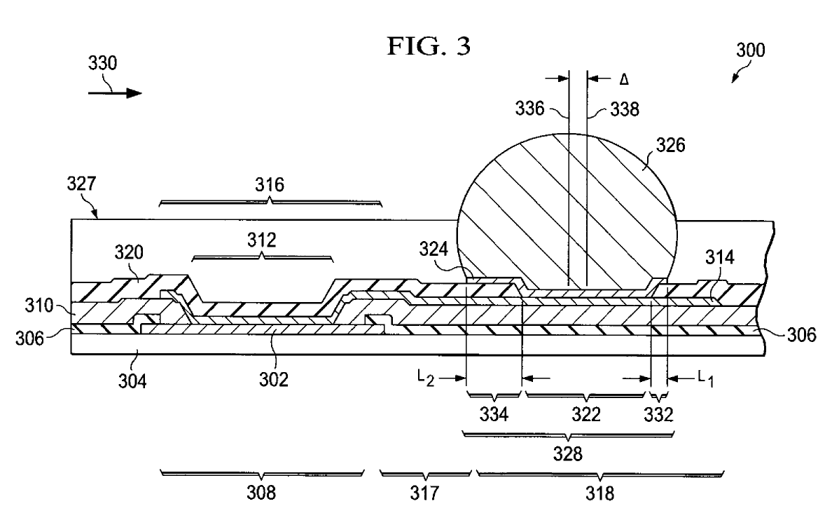

For example, FIG. 3 shows a cross-section of a portion of an exemplary WCSP-based integrated circuit (IC) device 300 with a lateral offset bump via according to the various embodiments of the present invention. In FIG. 3, IC device 300 can be formed using by first forming electrode pads 302 on a functional circuit die 304 having formed on or therein the functional circuit for the IC device 300. The electrode pads 302 can be formed from any type of electrically conductive material compatible with the materials used for forming the functional circuit die 304. For example, aluminum, copper, or any alloys thereof can be used with silicon-based circuits. However, the invention is not limited in this regard and generally any other type of electrically conductive material can be use to form the electrode pads 302.

After the electrode pads 302 are formed, a substrate passivation layer 306 can be formed on the functional circuit die 304 and the pads 302, having one or more rewiring openings or vias 308 for any subsequent RDL layers to contact the electrode pads 302. The passivation layer 306 can generally be formed from any dielectric material, including organic or inorganic dielectric materials. In additional, the passivation layer can also serve as a diffusion barrier to prevent diffusion of material into or out of the functional circuit die 304. Examples of such passivation layers include layers of silicon nitride comprising dielectric materials or silicon oxide comprising dielectric materials.

Alternatively or subsequent to the deposition and patterning of the passivation layer 306, a first interlayer dielectric film 310 can be deposited on the passivation layer 306 and the exposed portions of the electrode pads 302. Although any type of dielectric material can be used, in some embodiments of the present invention, a low thermal budget material can be used to prevent any damage to the functional circuit die 304. For example, polymer-based dielectric films, such as polyimide or bisbenzocyclobutene (BCB) can be used as a first interlayer dielectric film 310. Such materials can be easily deposited and patterned without requiring the high thermal budgets or advanced semiconductor wafer fabrication techniques typically required for inorganic dielectrics, such as silicon comprising dielectrics used in silicon wafer technologies. However, the invention is not limited in this regard, and the interlayer dielectric film can be formed from any organic or inorganic dielectric materials. Furthermore, the interlayer dielectric film 310 need not be a single film of a uniform composition. In some embodiments, a stack of different dielectric films of different compositions can be used to form the interlayer dielectric film 310.

After the interlayer dielectric film 310 is deposited, a second rewiring via 312 can be patterned over the electrode pads 302. However, it is within the scope of the present invention to concurrently pattern rewiring vias 308 and 312. Once the rewiring vias 308 and 312 are formed, the RDL 314 can be formed. For example, by deposition and patterning processes. In the various embodiments of the present invention, the RDL 314 can include one or more layers of electrically conductive materials. For example, the RDL 314 can be formed from a copper layer deposited on the first interlayer dielectric film 310 and in the rewiring vias 308 and 312. However, to improve adhesion of the copper layer to the first interlayer dielectric film and the exposed electrode pads 302, the RDL layer 314 can include one or more adhesion layers. Similarly, to reduce diffusion of copper or other lifetime killers, the RDL 314 can also one or more diffusion barrier layers. The RDL 314 can also include upper diffusion and/or adhesion layers to reduced diffusion and improved adhesion with subsequent layers. For example, the RDL can be any combination of tungsten, titanium, and copper layers or alloys thereof.

The resulting pattern of the RDL 314 can result in an electrode contacting pad 316 formed over and connected to the electrode pad 302. The resulting pattern of the RDL 314 can also define a rewiring pad 318 connected by RDL trace portion 317. Once the RDL 314 is formed, a second interlayer dielectric film 320 can be deposited, as described above for the first interlayer dielectric film 310. In some embodiments, the first and second interlayer dielectric films 310, 320 can have the same composition and thicknesses. However, the invention is not limited in this regard and the first and second can have different numbers of layers, different compositions, and/or different thicknesses depending on the requirements for the IC device 300. After the second interlayer dielectric film 320 is deposited, it can be patterned to provide bump openings or vias 322 over the rewiring pads 318.

After the bump openings 322 are formed, a UMB or bump pad layer 324 can be formed on the second interlayer dielectric film 320, followed by the bump or solder ball layer (not shown). Like the RDL 314, the bump pad layer 324 can be formed from a series of adhesion and/or barrier layers to allow the bump layer to properly adhere to the RDL 314 in the bump vias 322 and/or prevent diffusion between the bump layer and the RDL 314. For example, the bump pad layer 324 can be a combination of titanium, copper, nickel, and gold layers or alloys thereof, The bump pad layer 324 and bump layer can then be patterned to form bump pads 328 over bump vias 322. A subsequent thermal process can be used to reflow the bump layer portion of the bump pads 328 and form the solder ball or bump 326. A covering dielectric film 327 can also be formed over the second interlayer dielectric film 320 to further protect the IC device 300 or to provide additional mechanical support for the solder ball 326. Completed IC devices 300 formed on a semiconducting substrate can then be diced for use in electronic devices.

In conventional layouts, the rewiring pads 318, the bump vias 322, and the bump pads 328 are typically aligned with respect to each other. That is, in a typical layout, the center 336 of the bump pads 328 and rewiring pads 318 and the center 338 of the bump vias 322 are aligned to allow the two pads to connect through the second interlayer dielectric film 320. For example, in the case of the rewiring pads 318, the bump vias 322, and the bump pads 328 formed using circular-shaped features, a conventional layout would appear as a series of concentric circles. Such a layout provides increased process margin during alignment. However, in contrast, embodiments of the present invention provide for laterally offsetting the position of the bump vias 322 relative to that of the bump pads 328 and/or the rewiring pads 318 by an offset distance (Δ) in a direction 330 towards a neutral point of the die. In practice, this causes the DNP from the center of the bump vias 322 to be reduced relative to the DNP from the center of the bump pads 328 and the rewiring pads 318.

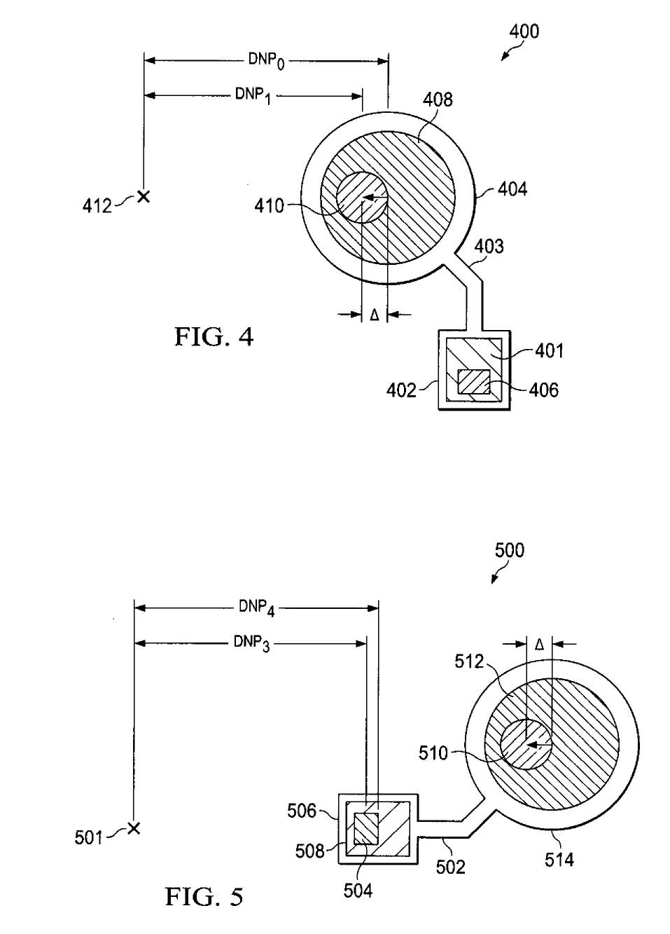

An exemplary layout 400 according to the various embodiments of the present invention is shown in FIG. 4. In FIG. 4, the layout 400 can include an electrode pad pattern 401, as well as any other patterns for forming the functional circuits for the WCSP device. The layout 400 can also include a RDL pattern 402 having a contact trace portion 403 and a RDL pad portion 404. The layout can further include a rewiring via pattern 406 for defining via in a first interlayer dielectric film. The layout 400 can further include a bump pad pattern 408 and a bump via pattern 410 for defining a via in a second interlayer dielectric film. Although the bump pad pattern 408, the bump via pattern 410 and the RDL pad portion 404 are shown as having circular shapes, the invention is not limited in this regard. The present invention is equally applicable to other shapes for the pads and the bump vias, such as rectangular pads and vias.

As a result of the lateral offset of the bump vias 410, the RDL pad portion 404, the bump pad pattern 408 and the bump via patterns 410 no longer form a series of concentric circles. Instead, at least some portions of the bump via patterns 410 are lateral offset towards the neutral point 412 of the WCSP device. Therefore, the DNP from the center of associated features of the bump pad and rewiring pad patterns 408, 404 stay the same (DNP₀), but the DNP for associated features in the bump via pattern are reduced (DNP₁) by an lateral offset amount (Δ=DNP₀−DNP₁). The lateral offset amount Δ can generally be any amount. However, in some embodiments to ensure sufficient process margin during fabrication of the WCSP device, the lateral offset amount Δ can be bounded to a minimum amount to ensure that a minimum RDL edge to bump via edge spacing and/or a minimum bump pad to bump via spacing is maintained. For example, as designed, the offset can be less than the minimum design rule spacing between the bump via edge and the RDL and/or UMB edge. However, even though the as-designed lateral offset can be fixed, in practice, the lateral offset amount Δ can vary by as much as 12%, due to processing variations.

The practical result of such a lateral offset is illustrated in FIG. 3. As shown in FIG. 3, the center 338 of bump via 322 can be laterally offset a distance (Δ) with respect to the center 336 of the bump pad 328 (and the rewiring pad 318) in a direction 330 towards the neutral point of the IC device 300. When such an lateral offset occurs, the length (L₁) of a near portion 332 of the second interlayer dielectric film 320 is reduced and the length (L₂) of a far portion 334 of the interlayer dielectric film is increased (L₁<L₂).

Typically, stress induced cracks and peeling propagate from an edge of the bump pad 328 and the covering film 327. The resulting cracks or peeling typically propagate through the far interlayer dielectric film portion 334 until they reach the RDL 314. At that point, if sufficient stress exists, the crack or peeling can continue to propagate along the interface between the RDL 314 and the far interlayer portion 334 until it reaches the edge of the bump via 322. At that point, the stress induced at this edge of the bump via 322 by the cracks or peeling combined with the stress naturally occurring at this edge, as described above for FIG. 2, is typically sufficient to induce cracks or peeling in the RDL 314 and/or the first interlayer dielectric film 310 below the edge of the bump via 322. This cracking or peeling typically results in the reliability failures observed for WCSPs, particularly when cracks or peeling occur in a contact trace portion 317 of the RDL 314.

In the various embodiments of the present invention, by increasing the length of the far interlayer portion 334, the amount of stress required to induce the reliability failures is also generally increased. In particular, to induce a reliability failure, additional stress will generally be required to propagate the cracking or peeling the additional length of the far interlayer portion 334. Therefore overall higher stress will be required to induce reliability failures by cracking or peeling of the RDL 314 or other layers, improving overall reliability of the WCSP device.

In some embodiments of the present invention, the lateral offset can be applied equally to all bump vias. However in other embodiments of the present invention, the lateral offsets can be applied more selectively. For example, lateral offsets can be applied only at bump vias associated with stresses exceeding a threshold amount. We only have normal and shear stress relative to one another, not threshold stress (i.e. the point at which failure occurs). In such cases, if a stress pattern is available, such as that in FIG. 1, the lateral offsets can be applied only to those bump vias outside region 104. Furthermore, the certain amounts of lateral offset can be associated with different levels of stress. For example, as previously described, higher stress is typically associated with bump pads at the corners of the dies. In such cases, a higher amount of lateral offset can be provided to bump vias in these regions and a lower amount of lateral offset can be provided for bump vias along a single edge of the WCSP device. In yet another example, for WCSP devices having high and low density regions associated with different stress amounts, the lateral offset can be applied to only those bump vias in the higher stress region.

In still other embodiments, the lateral offset can be applied as a function of the number of bump pads formed. For example, the Present inventor has discovered that for a 9×9 array of bump pads, little or no lateral offset is generally needed. However, as the number of bump pads is increased and/or the area of the die is increased, one or more of the bump vias can require a lateral offset to reduce stress induced reliability failures.

In yet other embodiments, the lateral offsets can be applied to bump vias associated with RDL features associated with known failure modes. For example, the lateral offset can be applied only to bump vias associated with RDL contact traces extending in a direction away from the neutral point of the die, as illustrated in FIGS. 3 and 4. Therefore, the lateral offsets can be applied only to those bump vias likely to sever the contact trace of the RDL.

In still other embodiments of the present invention, via lateral offsets can be applied to other vias of the RDL structure, as any other vias within the polyimide layers are equally susceptible to stress failures due to die bowing. In particular, as shown in FIG. 5, a RDL trace 502 can also be severed, at least partially by any cracks due to increased stress at electrode pad vias 504 for contacting the electrode contacting pads 506 and the electrode pad 508. In such embodiments, electrode pad contacting vias 504 can be laterally offset globally or selectively relative to a neutral point 501 to reduce their DNP (i.e., DNP₃<DNP₄). Furthermore, any configuration of lateral offsets for electrode pad contacting vias 504 can be combined with a same or different configuration of lateral offsets (Δ) in bump pad vias 510 for contacting UMB pads 512 and RDL pads 514. That is, the WCSP device can be formed using lateral offsets in the bump vias 510, the electrode pad contacting vias 508, or both.

In the various embodiments of the present invention, the lateral offsets can be applied in various ways. For example, an automated circuit layout tool can be configured to automatically adjust bump pad via placement based on modeled, empirical data or on one or more preferences or criteria specified by the user. More specifically, the automated layout tool can be provided with the location of the neutral point of the WCSP die or the stress distribution for the die. The inventors have found that in many cases, the neutral point of the die can be estimated on the distribution of solder balls and the associated RDL pattern. In such cases, the neutral point of the die can be estimated to be the center of the solder ball matrix, as it is typically in sufficient proximity to the actual neutral point for purposes of specifying lateral offsets. Accordingly, a designer can generate the WCSP device layout without lateral offsets and the automated tool can automatically configure the layout to provide any necessary lateral offsets. However, the invention is not limited to solely automated generation of lateral offsets and a design can manually adjust bump vias based on any criteria. Regardless of how the layout is generated, the final layout including lateral offsets can be used to generate the necessary masks for fabricating the WCSP device.

These are but a few examples. Accordingly, the breadth and scope of the present invention should not be limited by any of the above described embodiments. Rather, the scope of the invention should be defined in accordance with the following claims and their equivalents.

Although the invention has been illustrated and described with respect to one or more implementations, equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and/or the claims, such terms are intended to be inclusive in a manner similar to the term “comprising.”

The Abstract of the Disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the following claims.

What is claimed is:

1. An integrated circuit device, comprising:
a functional circuit die;
a patterned rewiring layer formed on said die, said patterned rewiring layer defining a first rewiring pad and one or more second rewiring pads on an opposite side of a neutral point of said die;
at least one dielectric layer formed on said patterned rewiring layer and said functional circuit die, said dielectric layer having a first bump opening feature over said first rewiring pad and second bump opening features over each of said second rewiring pads;
an electrically conductive first bump pad feature formed on said dielectric layer over said first bump opening feature; and
electrically conductive second bump pad features formed on said dielectric layer over each of said second bump opening features,
wherein said first and said second bump pad features make contact with said first and said second rewiring pads via said first and said second bump opening features, wherein a center of said first bump opening feature is laterally offset from a center of said first bump pad feature towards said neutral point of said die, and wherein a center of each of said second bump opening features is laterally offset from a center of said associated second bump pad feature towards said neutral point of said die.

2. The integrated circuit device of claim 1, wherein an amount of said lateral offsets for each of said first and said second bump opening features are less than a design rule minimum spacing between an edge of said bump opening features and an edge of said bump pad features.

3. The integrated circuit device of claim 2, wherein said lateral offset amount of said first bump opening is greater than said lateral offset amount for said second bump openings.

4. The integrated circuit device of claim 1, wherein said patterned rewiring layer defines at least two second rewiring pads.

5. The integrated circuit device of claim 4, wherein a first of said two second rewiring pads is closer to said neutral point of said die than a second of said two second rewiring pads, and wherein said lateral offset amount for said second bump opening feature for said first of said two second rewiring pads is less than said lateral offset amount for said second of said two second rewiring pads.

6. The integrated circuit device of claim 4, wherein a first of said two second rewiring pads is closer to a corner of said die than a second of said two second rewiring pads, and wherein said lateral offset amount for said second bump opening feature for said first of said two second rewiring pads is greater than said lateral offset amount for said second of said two second rewiring pads.

7. A mask set for an integrated circuit device, comprising:
a plurality of mask for forming a functional circuit die;
a rewiring layer mask for forming a patterned a rewiring layer on said die, said patterned rewiring layer defining a first rewiring pad and one or more second rewiring pads on an opposite side of a neutral point of said die;
a bump opening mask layer for forming in at least one dielectric layer formed on said patterned rewiring layer and said functional circuit die a first bump opening feature over said first rewiring pad and second bump opening features over each of said second rewiring pads;
a bump pad mask for forming in an electrically conductive layer over said dielectric layer a first bump pad feature over said first bump opening feature and a second bump pad features over each of said second bump opening features,
wherein said first and said second bump pad features make contact with said first and said second rewiring pads via said first and said second bump opening features, wherein a center of said first bump opening feature is laterally offset from a center of said first bump pad feature towards said neutral point of said die, and wherein a center of each of said second bump opening features is laterally offset from a center of said associated second bump pad feature towards said neutral point of said die.

8. The mask set of claim 7, wherein an amount of said lateral offsets for each of said first and said second bump opening features in said bump pad mask are less than a design rule minimum spacing between an edge of said bump opening features and an edge of said bump pad features multiplied by a scaling factor for said bump pad mask.

9. The mask set of claim 8, wherein said lateral offset amount of said first bump opening is greater than said lateral offset amount for said second bump openings.

10. The mask set of claim 7, wherein said rewiring layer mask further defines at least two second rewiring pads.

11. The mask set of claim 10, wherein a first of said two second rewiring pads is closer to said neutral point of said die than a second of said two second rewiring pads, and wherein said lateral offset amount for said second bump opening feature for said first of said two second rewiring pads is less than said lateral offset amount for said second of said two second rewiring pads.

12. The mask set of claim 10, wherein a first of said two second rewiring pads is closer to a corner of said die than a second of said two second rewiring pads, and wherein said lateral offset amount for said second bump opening feature for said first of said two second rewiring pads is greater than said lateral offset amount for said second of said two second rewiring pads.

13. A method for designing an integrated circuit device, comprising:
providing a functional circuit die design;
identifying a neutral point of said die;
generating a rewiring layer design for forming a patterned a rewiring layer on said die, said patterned rewiring layer defining a first rewiring pad and one or more second rewiring pads on an opposite side of said neutral point of said die;
generating a bump opening layer design for forming in at least one dielectric layer formed on said patterned rewiring layer and said functional circuit die a first bump opening feature over said first rewiring pad and second bump opening features over each of said second rewiring pads; and
generating a bump pad layer design for forming in an electrically conductive layer over said dielectric layer a first bump pad feature over said first bump opening feature and second bump pad features over each of said second bump opening features,
wherein said first and said second bump pad features are designed to make contact with said first and said second rewiring pads via said first and said second bump opening features, wherein a center of said first bump opening feature is laterally offset from a center of said first bump pad feature towards said neutral point of said die, and wherein a center of each of said second bump opening features is laterally offset from a center of said associated second bump pad feature towards said neutral point of said die.

14. The method of claim 13, wherein an amount of said lateral offsets for each of said first and said second bump opening features is selected to be less than a design rule minimum spacing between an edge of said bump opening features and an edge of said bump pad features.

15. The method of claim 14, wherein said lateral offset amount of said first bump opening is selected to be greater than said lateral offset amount for said second bump openings.

16. The method of claim 13, wherein said patterned rewiring layer defines at least two second rewiring pads.

17. The method of claim 16, wherein a first of said two second rewiring pads is closer to said neutral point of said die than a second of said two second rewiring pads, and wherein said lateral offset amount for said second bump opening feature for said first of said two second rewiring pads is selected to be less than said lateral offset amount for said second of said two second rewiring pads.

18. The method of claim 16, wherein a first of said two second rewiring pads is closer to a corner of said die than a second of said two second rewiring pads, and wherein said lateral offset amount for said second bump opening feature for said first of said two second rewiring pads is selected to be greater than said lateral offset amount for said second of said two second rewiring pads.

19. The method of claim 13, wherein said identifying farther comprises:
selecting a geometric center of said die.

20. The method of claim 13, wherein said identifying further comprises:
selecting a center of a bump pad matrix for said die.
